(19) United States
(12) Patent Application Publication
(10) Pub. No.: US 2015/0359082 A1
(43) Pub. Date: Dec. 10, 2015

(54) CABLE WITH CONNECTORS AND CONNECTOR

(71) Applicant: Hitachi Metals, Ltd., Tokyo (JP)

(72) Inventors: Kei NISHIMURA, Hitachi (JP); Izumi Fukasaku, Hitachi (JP); Takahiro Sugiyama, Hitachi (JP)

(21) Appl. No.: 14/726,280

(22) Filed: May 29, 2015

(30) Foreign Application Priority Data
Jun. 4, 2014 (JP) 2014-115949

(51) Int. Cl. H05K 1/02; H01R 13/66; H01P 3/08

(52) U.S. Cl. CPC H05K 1/025; H01P 3/08; H05K 1/0216; H01R 13/665

(57) ABSTRACT

A cable with connectors includes a differential transmission path disposed in a paddle card and configured to allow transmission of differential signals between a device and differential signal transmission cables; a chip component mounted on the differential transmission path; and a plurality of foot pads disposed on the differential transmission path to allow mounting of the chip component, the foot pads being greater in width than traces forming the differential transmission path. The differential transmission path has a high-impedance portion at a connection thereof to the foot pads. The high-impedance portion has a differential impedance higher than that of the differential transmission path excluding the high-impedance portion.

The present application is based on Japanese patent application No. 2014-115949 filed on Jun. 4, 2014, the entire contents of which are incorporated herein by reference.

### BACKGROUND OF THE INVENTION

1. Field of the Invention

The present invention relates to a cable with connectors and a connector.

2. Description of the Related Art

A cable with connectors is known, which includes a cable including a plurality of differential signal transmission cables, connectors at respective ends of the cable, and a paddle card included in each of the connectors and configured to electrically connect the differential signal transmission cables to a device to be connected. The paddle card includes a differential transmission path for transmission of differential signals between the device and the differential signal transmission cables.

In the cable with connectors, a chip component is mounted on the differential transmission path. For example, a chip capacitor for cutting off direct current is mounted on the differential transmission path on the receiving side of the paddle card. As illustrated in FIG. 7, in a cable with connectors 71 of related art, foot pads 73 for mounting a chip component are patterned on a differential transmission path 72. The foot pads 73 are typically formed to be greater in width than traces forming the differential transmission path 72.

For example, Japanese Unexamined Patent Application Publication No. 2011-90959 discloses a technique related to the invention of the present application.

In the cable with connectors 71 of related art, where the foot pads 73 are greater in width than the traces forming the differential transmission path 72, the capacitance increases in the area where the foot pads 73 are disposed. The increased capacitance in this area and the capacitance of the chip component to be mounted result in lower differential impedance. This causes impedance mismatching in the area where the foot pads 73 are disposed, and leads to increased crosstalk caused by reflection.

### SUMMARY OF THE INVENTION

An object of the present invention is to solve the problems described above, and to provide a cable with connectors and a connector in which crosstalk caused by reflection resulting from impedance mismatching can be reduced.

The present invention has been made to achieve the object described above. A cable with connectors according to an aspect of the present invention includes a cable including a plurality of differential signal transmission cables; connectors at respective ends of the cable; a paddle card included in each of the connectors and configured to electrically connect the differential signal transmission cables to a device to be connected; a differential transmission path disposed in the paddle card and configured to allow transmission of differential signals between the device and the differential signal transmission cables; a chip component mounted on the differential transmission path; and a plurality of foot pads disposed on the differential transmission path to allow mounting of the chip component, the foot pads being greater in width than traces forming the differential transmission path. The differential transmission path has a high-impedance portion at a connection thereof to the foot pads. The high-impedance portion has a differential impedance higher than that of the differential transmission path excluding the high-impedance portion.

The high-impedance portion may be formed by narrowing the traces forming the differential transmission path.

A length of the high-impedance portion may be from 2% to 4% of a wavelength corresponding to an operating frequency which takes into account a wavelength reduction effect of a dielectric included in the paddle card.

The high-impedance portion may be formed by widening a spacing between the traces forming the differential transmission path.

The foot pads may each be obtained by being formed into a rectangular shape and cutting off a corner of the foot pad. The corner is located opposite a connection of one of the traces forming the differential transmission path to the foot pad, and is located to a side of the other of the traces forming the differential transmission path.

A connector according to another aspect of the present invention is at an end of a cable including a plurality of differential signal transmission cables. The connector includes a paddle card configured to electrically connect the differential signal transmission cables to a device to be connected; a differential transmission path disposed in the paddle card and configured to allow transmission of differential signals between the device and the differential signal transmission cables; a chip component mounted on the differential transmission path; and a plurality of foot pads disposed on the differential transmission path to allow mounting of the chip component, the foot pads being greater in width than traces forming the differential transmission path. The differential transmission path has a high-impedance portion at a connection thereof to the foot pads.

The high-impedance portion has a differential impedance higher than that of the differential transmission path excluding the high-impedance portion.

According to the above-described aspects of the present invention, a cable with connectors and a connector can be provided, in which crosstalk caused by reflection resulting from impedance mismatching can be reduced.

### BRIEF DESCRIPTION OF THE DRAWINGS

FIG. 1A is a plan view of a cable with connectors according to an embodiment of the present invention, and FIG. 1B is a plan view of part of a differential transmission path in the cable with connectors.

FIG. 2 is a graph showing differential impedances measured near foot pads in both the cable with connectors of FIGS. 1A and 1B and a cable with connectors of a related example.

FIG. 3 is a plan view of part of a differential transmission path in a cable with connectors according to another embodiment of the present invention.

FIG. 4A is a cross-sectional view of a paddle card used as a computation model in the present invention, and FIG. 4B is a graph showing a relationship between a differential impedance and a common mode impedance with respect to a spacing between traces forming a differential transmission path in the paddle card illustrated in FIG. 4A.

FIG. 5A is a graph showing an exemplary setting of differential impedance in differential signal transmission cables, paddle card, and device, and FIG. 5B is a graph showing an exemplary setting of common mode impedance in differential signal transmission cables, paddle card, and device.

FIG. 6 is a plan view of part of a differential transmission path in a cable with connectors according to another embodiment of the present invention.

FIG. 7 is a plan view of part of a differential transmission path in a cable with connectors of related art.

### DESCRIPTION OF THE PREFERRED EMBODIMENTS

Embodiments of the present invention will now be described with reference to the attached drawings.

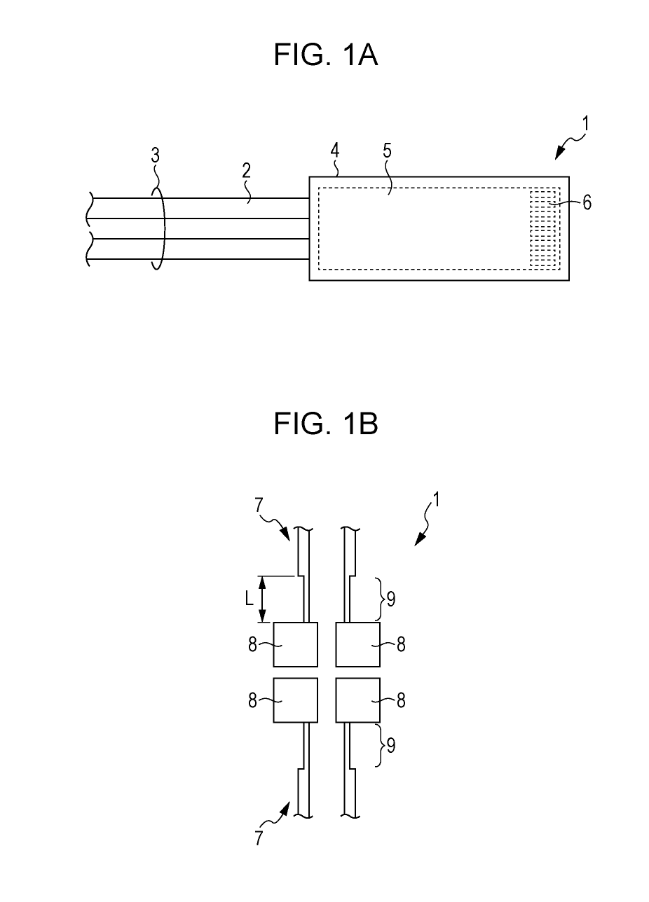

FIG. 1A is a plan view of a cable with connectors according to an embodiment, and FIG. 1B is a plan view of part of a differential transmission path in the cable with connectors.

A cable with connectors 1 illustrated in FIGS. 1A and 1B includes a cable 3 including a plurality of differential signal transmission cables 2, connectors 4 at respective ends of the cable 3, and a paddle card 5 included in each of the connectors 4 and configured to electrically connect the differential signal transmission cables 2 to a device (not shown) to be connected.

For example, when the cable with connectors 1 is configured to allow transmission and reception on four channels, the cable with connectors 1 includes a total of eight differential signal transmission cables 2, including four for transmission and four for reception.

A plurality of electrodes 6 to be electrically connected to the device are disposed on one end portion of the paddle card 5 (i.e., the one end portion being opposite the other end portion thereof connected to the cable 3). Although not shown, ground electrodes, power electrodes, control signal electrodes, and the like are aligned on a surface of the one end portion of the paddle card 5 to form a card edge connector. The electrodes forming the card edge connector are arranged, for example, as defined in SFF-8436 Specification for QSFP+ 10 Gbs 4× PLUGGABLE TRANSCEIVER Rev 4.4.

A plurality of cable connection electrodes (not shown) to which the differential signal transmission cables 2 are electrically connected are disposed on the other end portion of the paddle card 5 (i.e., the other end portion connected to the cable 3).

The paddle card 5 includes a differential transmission path 7 for transmission of differential signals between the device and the differential signal transmission cables 2. The differential transmission path 7 is formed by traces (microstrip lines) that connect the electrodes 6 to the cable connection electrodes.

Although not shown, a chip component is mounted on the differential transmission path 7. The chip component is, for example, a chip capacitor designed to cut off direct current and mounted on the differential transmission path 7 on the receiving side. In the present specification, outputting electric signals from the paddle card 5 to the differential signal transmission cables 2 is referred to as transmission, and inputting electric signals from the differential signal transmission cables 2 to the paddle card 5 is referred to as reception.

A plurality of foot pads 8 for mounting the chip component are disposed on the differential transmission path 7. The chip component is mounted on the differential transmission path 7, for example, by being soldered and electrically connected to the foot pads 8.

The foot pads 8 are formed to be greater in width than the traces forming the differential transmission path 7. The foot pads 8 used here are rectangular in shape.

In the cable with connectors 1 according to the present embodiment, the differential transmission path 7 has a high-impedance portion 9 at a connection thereof to the foot pads 8. The high-impedance portion 9 has a differential impedance higher than that of the differential transmission path 7. Although the high-impedance portion 9 is treated as part of the differential transmission path 7 in the present specification, the expression “the high-impedance portion 9 has a differential impedance higher than that of the differential transmission path 7” means that the high-impedance portion 9 has a differential impedance higher than that of the differential transmission path 7 excluding the high-impedance portion 9.

In the present embodiment, the high-impedance portion 9 is formed by narrowing the traces forming the differential transmission path 7. Here, the differential impedance of the differential transmission path 7, excluding the high-impedance portion 9, is 100Ω, and the differential impedance of the high-impedance portion 9 is 140Ω (which is 1.4 times the differential impedance of the differential transmission path 7 excluding the high-impedance portion 9).

Since the foot pads 8 are greater in width than the traces forming the differential transmission path 7, the capacitance increases at the position of the foot pads 8 and the differential impedance expressed by the following equation (1) decreases:

Z_{diff}=(L/C)^{1/2} (1)

where Z_{diff} is differential impedance, L is inductance, and C is capacitance. When the high-impedance portion 9 with high differential impedance is disposed immediately before the foot pads 8, impedance mismatching can be reduced on the whole in a relatively low frequency band (25 GHz or less).

A length L of the high-impedance portion 9 is preferably from 2% to 4% of a wavelength λ corresponding to an operating frequency which takes into account a wavelength reduction effect of a dielectric included in the paddle card 5. More preferably, the length L of the high-impedance portion 9 is about 3% of the wavelength λ. This is because if the length L of the high-impedance portion 9 is as short as less than 2% of the wavelength λ, the impedance mismatching reduction effect of the high-impedance portion 9 cannot be fully achieved, whereas if the length L of the high-impedance portion 9 is greater than 4% of the wavelength λ, impedance mismatching caused by the high-impedance portion 9 may occur.

Here, the operating frequency is 25 Gbit/s (fundamental frequency 12.5 GHz), the dielectric constant of the paddle card 5 is 3.6 (which is a dielectric constant at 10 GHz), and the wavelength λ which takes into account the wavelength reduction effect is about 10.26 mm. Thus, the length L of the high-impedance portion 9 is 0.3 mm, which is about 3% of the wavelength λ.

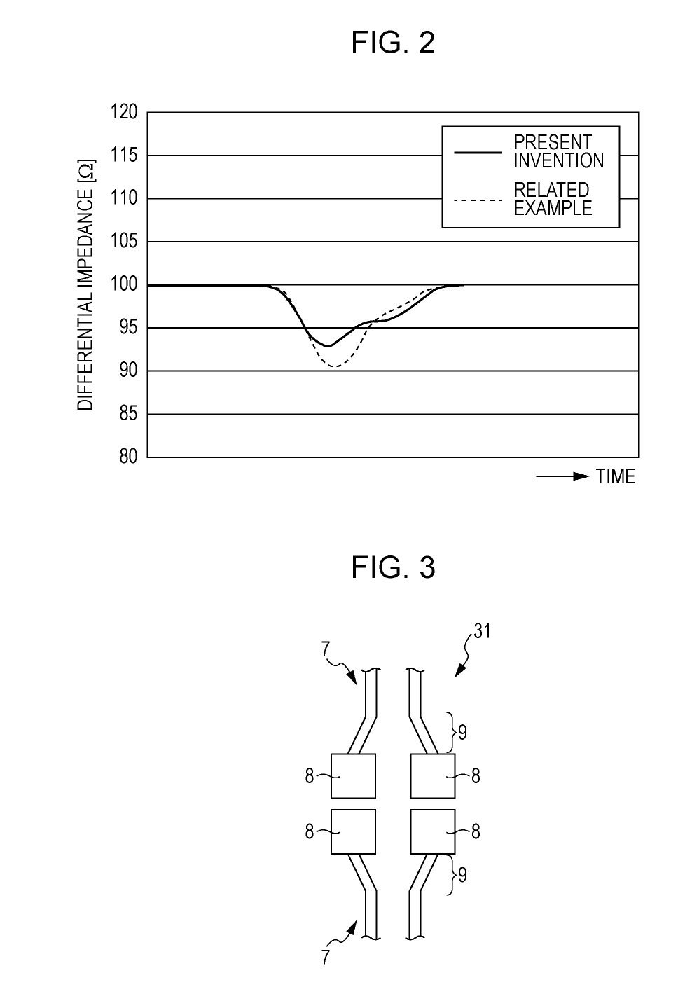

Referring to FIG. 2, a broken line represents a differential impedance measured near the foot pads 8 in a related example where the high-impedance portion 9 is not provided, and a solid line represents a differential impedance measured near the foot pads 8 in the present invention where the high-impedance portion 9 is provided. In FIG. 2, the horizontal axis represents time because the differential impedances are determined on the basis of SDD11 and SCC11, which are S-parameters. In other words, the horizontal axis represents position in the transmission path (or distance from a measurement point).

FIG. 2 shows that, with the high-impedance portion 9 having a length L of 0.3 mm and a differential impedance of 140Ω, the minimum differential impedance is improved by about 2.4Ω from 90.5Ω to 92.9Ω and impedance mismatching is reduced.

As described above, in the cable with connectors 1 of the present embodiment, the differential transmission path 7 has, at a connection thereof to the foot pads 8, the high-impedance portion 9 having a differential impedance higher than that of the differential transmission path 7.

This makes it possible to achieve a pseudo increase in differential impedance at the position of the foot pads 8 and reduce impedance mismatching. It is thus possible to reduce crosstalk caused by reflection resulting from impedance mismatching.

Other embodiments of the present invention will now be described.

A cable with connectors 31 illustrated in FIG. 3 differs from the cable with connectors 1 illustrated in FIGS. 1A and 1B in that the high-impedance portion 9 is formed by widening the spacing between the traces forming the differential transmission path 7. In the cable with connectors 31, the spacing between the traces forming the differential transmission path 7 is gradually widened toward the foot pads 8. Alternatively, the traces forming the differential transmission path 7 may be bent into a crank (or stepped) shape so that the spacing between them can be kept the same in the high-impedance portion 9.

Widening the spacing between the traces forming the differential transmission path 7 increases the loop area (i.e., the area of current loop), so that the inductance increases in proportion to the loop area. Thus, from the equation (1) described above, the differential impedance can be increased and impedance mismatching at the position of the foot pads 8 can be reduced.

By widening the spacing between the traces forming the differential transmission path 7 to form the high-impedance portion 9, the spacing between the foot pads 8 is also widened. This facilitates mounting of a chip component and allows use of a chip component of larger size.

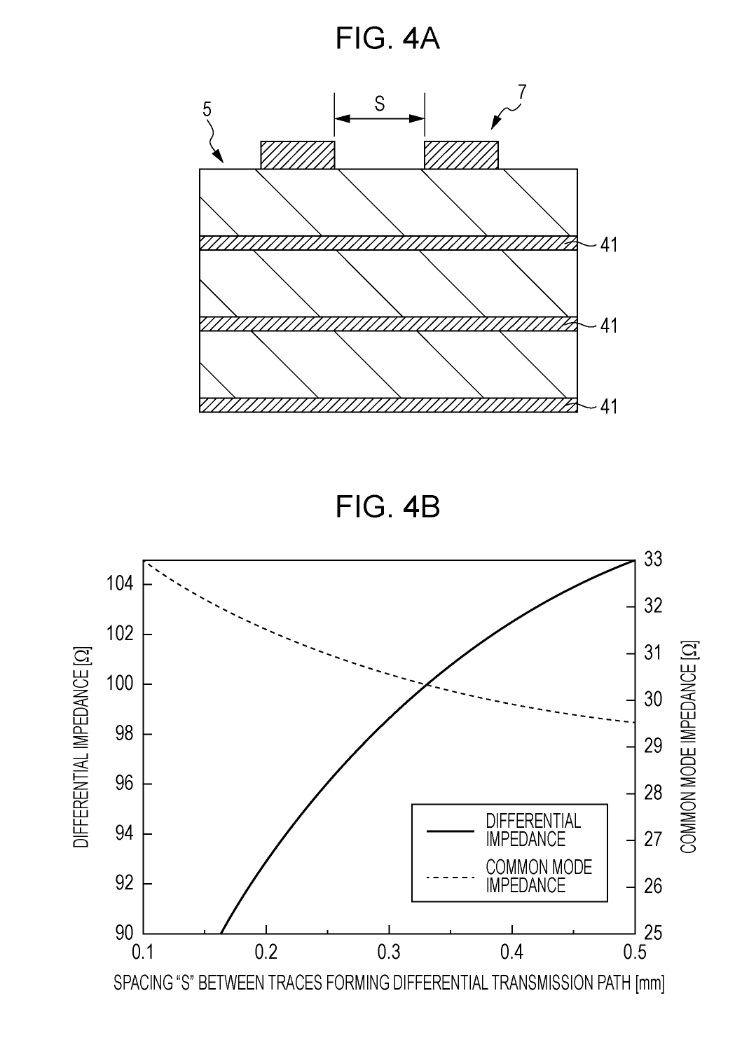

Referring to FIG. 4A, a four-layer substrate is used as the paddle card 5, in which the differential transmission path 7 serves as the first layer and ground layers 41 serve as the second to fourth layers. FIG. 4B shows a differential impedance and a common mode impedance obtained by varying a spacing S between traces forming the differential transmission path 7 illustrated in FIG. 4A.

As shown in FIG. 4B, as the spacing S between the traces forming the differential transmission path 7 increases, the differential impedance increases and the common mode impedance decreases. The spacing S between the traces forming the differential transmission path 7 may be adjusted to achieve optimum differential and common mode impedances.

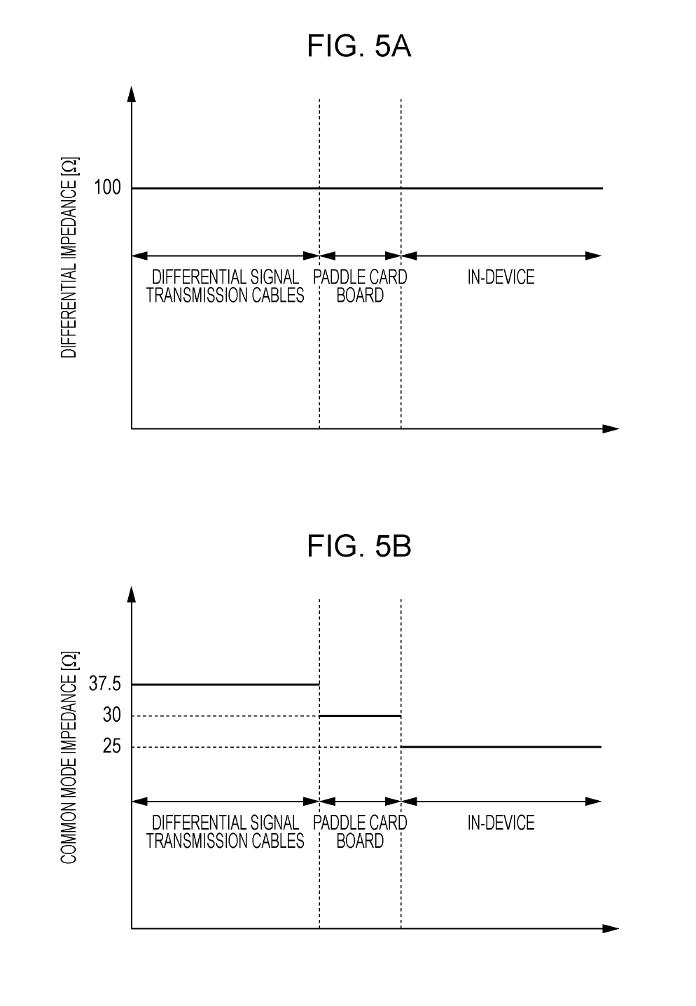

For example, if the differential signal transmission cables 2 have a differential impedance of 100Ω and a common mode impedance of 37.5Ω and the device has a differential impedance of 100Ω and a common mode impedance of 25Ω, it is preferable to make an adjustment, as shown in FIGS. 5A and 5B, such that the differential impedance and the common mode impedance of the paddle card 5 (differential transmission path 7) are about 100Ω and about 30Ω, respectively. In this case, the spacing S between the traces forming the differential transmission path 7 may be adjusted, at the high-impedance portion 9, such that the differential impedance and the common mode impedance at the position of the foot pads 8 are about 100Ω and about 30Ω, respectively.

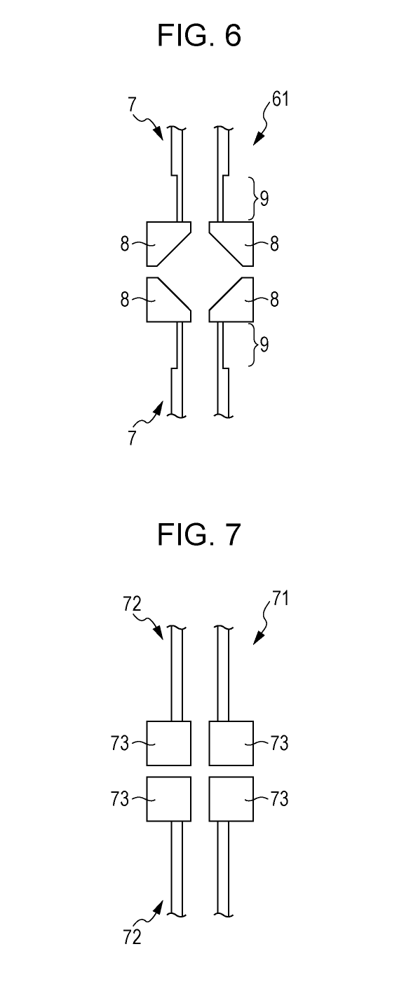

A cable with connectors 61 illustrated in FIG. 6 is obtained by cutting off an inside portion of each of the foot pads 8 in the cable with connectors 1 illustrated in FIGS. 1A and 1B.

Specifically, in the cable with connectors 61, the foot pads 8 are each obtained by being formed into a rectangular shape and then cutting off a corner of the foot pad 8. The corner of the foot pad 8 is located opposite a connection of one of the traces forming the differential transmission path 7 to the foot pad 8, and also located to a side of the other of the traces forming the differential transmission path 7 (i.e., located inside the differential transmission path 7).

Cutting off the inside portion (corner) of each of the foot pads 8 can reduce capacitive coupling at the position where the foot pads 8 are disposed, and can further reduce lowering of differential impedance.

It is obvious that the present invention is not limited to the embodiments described above, and various changes can be made thereto within the scope of the present invention.

For example, although the high-impedance portion 9 is formed either by narrowing the traces forming the differential transmission path 7, or by widening the spacing between the traces forming the differential transmission path 7 in the embodiments described above, the high-impedance portion 9 may be formed by combination of these configurations. That is, the high-impedance portion 9 may be formed by narrowing the traces forming the differential transmission path 7, and then widening the spacing between the traces forming the differential transmission path 7.

What is claimed is:

1. A cable with connectors, comprising:
a cable including a plurality of differential signal transmission cables;
connectors at respective ends of the cable;
a paddle card included in each of the connectors and configured to electrically connect the differential signal transmission cables to a device to be connected;
a differential transmission path disposed in the paddle card and configured to allow transmission of differential signals between the device and the differential signal transmission cables;
a chip component mounted on the differential transmission path; and
a plurality of foot pads disposed on the differential transmission path to allow mounting of the chip component, the foot pads being greater in width than traces forming the differential transmission path,
wherein the differential transmission path has a high-impedance portion at a connection thereof to the foot pads, the high-impedance portion having a differential impedance higher than that of the differential transmission path excluding the high-impedance portion.

2. The cable with connectors according to claim 1, wherein the high-impedance portion is formed by narrowing the traces forming the differential transmission path.

3. The cable with connectors according to claim 2, wherein a length of the high-impedance portion is from 2% to 4% of a wavelength corresponding to an operating frequency which takes into account a wavelength reduction effect of a dielectric included in the paddle card.

4. The cable with connectors according to claim 1, wherein the high-impedance portion is formed by widening a spacing between the traces forming the differential transmission path.

5. The cable with connectors according to claim 1, wherein the foot pads are each obtained by being formed into a rectangular shape and cutting off a corner of the foot pad, the corner being located opposite a connection of one of the traces forming the differential transmission path to the foot pad, the corner being located to a side of the other of the traces forming the differential transmission path.

6. A connector at an end of a cable including a plurality of differential signal transmission cables, the connector comprising:
a paddle card configured to electrically connect the differential signal transmission cables to a device to be connected;
a differential transmission path disposed in the paddle card and configured to allow transmission of differential signals between the device and the differential signal transmission cables;
a chip component mounted on the differential transmission path; and
a plurality of foot pads disposed on the differential transmission path to allow mounting of the chip component, the foot pads being greater in width than traces forming the differential transmission path,
wherein the differential transmission path has a high-impedance portion at a connection thereof to the foot pads, the high-impedance portion having a differential impedance higher than that of the differential transmission path excluding the high-impedance portion.

7. The connector according to claim 6, wherein the high-impedance portion is formed by narrowing the traces forming the differential transmission path.

8. The connector according to claim 7, wherein a length of the high-impedance portion is from 2% to 4% of a wavelength corresponding to an operating frequency which takes into account a wavelength reduction effect of a dielectric included in the paddle card.

9. The connector according to claim 6, wherein the high-impedance portion is formed by widening a spacing between the traces forming the differential transmission path.

10. The connector according to claim 6, wherein the foot pads are each obtained by being formed into a rectangular shape and cutting off a corner of the foot pad, the corner being located opposite a connection of one of the traces forming the differential transmission path to the foot pad, the corner being located to a side of the other of the traces forming the differential transmission path.
